(19) United States
(12) Patent Application Publication
(10) Pub. No.: US 2007/0029571 A1
(43) Pub. Date: Feb. 8, 2007

(54) Nitride semiconductor light-emitting device

(75) Inventors: Daisuke Hanaoka, Soraku-Gun (JP); Masaya Ishida, Hiroshima (JP); Kunihiro Takatani, Hiroshima (JP); Shigetoshi Ito, Osaka (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/496,524

(22) Filed: Aug. 1, 2006

(30) Foreign Application Priority Data
Aug. 2, 2005 (JP) 2005-223582
Jun. 21, 2006 (JP) 2006-170988

(51) Int. Cl. H01L 33/00

(52) U.S. Cl. 257/99; 257/100; 257/E33.058

(57) ABSTRACT

In a nitride semiconductor light-emitting device, a cap is pressure-bonded on the top surface of a stem under electric discharge to form a package. The package encloses a heatsink, a nitride semiconductor laser element, electrode pins, and wires, and has sealed inside it a gas containing oxygen as a sealed atmosphere. At least the inner surface of the cap is plated with Ni and Pd, which are metals that can occlude hydrogen.

This nonprovisional application claims priority under 35 U.S.C. §119(a) on Patent Applications Nos. 2005-223582 and 2006-170988 filed in Japan on Aug. 2, 2005 and Jun. 21, 2006, respectively, the entire contents of which are hereby incorporated by reference.

### BACKGROUND OF THE INVENTION

1. Field of the Invention

The present invention relates to a light-emitting device employing a nitride semiconductor light-emitting element, and more particularly to the package of such a light-emitting device.

2. Description of Related Art

Conventionally, as semiconductor light-emitting devices such as semiconductor laser devices, can-packaged products have been widely used. In a can-packaged semiconductor laser device, a heatsink, a semiconductor laser element, and the like mounted on a stem are sealed inside a cap. For example, in the semiconductor laser device proposed in JP-A-H10-313147, to prevent a semiconductor laser element and the like from being exposed to high temperature when a cap is molded, an inert gas is sealed in the space surrounded by the cap and a stem.

In a can-packaged semiconductor laser device, to permit pressure-bonding of a cap to a stem under electric discharge and for other reasons, a metal such as Pd or Ni is often used in the inner surface of the stem and the cap, that is, in the inward-facing part of the package that the stem and the cap together form. This metal has a property of being able to occlude hydrogen atoms. Thus, in the semiconductor laser device proposed in JP-A-H10-313147 mentioned above, when it is driven for a long time, as the semiconductor laser element generates heat and the semiconductor laser device as a whole becomes hot, the hydrogen atoms occluded in the metal may be released, as hydrogen molecules, into the inert gas sealed inside.

On the other hand, it is known that a p-type semiconductor doped with an acceptor impurity exhibits a change in its resistivity as it is heated in a hydrogen atmosphere. For example, when a film formed of a p-type nitride semiconductor obtained by doping a nitride semiconductor AlₓGa_{y}In_{z}N (where 0≦x≦1, 0≦y≦1, 0≦z≦1, and x+y+z=1) with Mg as an acceptor impurity is heat-treated in a hydrogen atmosphere, its resistivity increases.

That is, in a semiconductor laser device in which a material that can occlude hydrogen is used in the inward-facing part of the package thereof, if a nitride semiconductor laser element is used as its semiconductor laser element, under the influence of hydrogen molecules released while the semiconductor laser device is driven, the resistivity of a p-type semiconductor used therein may increase, and thus its driving voltage may increase, destabilizing the characteristics of the laser light emitted therefrom.

### SUMMARY OF THE INVENTION

An object of the present invention is to provide a nitride semiconductor light-emitting device that stably emits laser light despite a material that can occlude hydrogen being used in the package thereof.

To achieve the above object, according to the present invention, a nitride semiconductor light-emitting device is provided with: a package composed of a stem and a cap fitted on the stem; a nitride semiconductor light-emitting element provided inside the package; and a sealed gas sealed inside the package. Here, a material that can occlude hydrogen is provided inside the package, and the sealed gas contains oxygen.

According to the present invention, in the semiconductor laser device described above, the material that can occlude hydrogen may be formed in the inner surface of the cap.

According to the present invention, in the semiconductor laser device described above, the material that can occlude hydrogen may contain at least one type of metal selected from the group of Ti, Zr, Hf, V, Nb, Ta, Ni, and Pd.

According to the present invention, in the semiconductor laser device described above, the sealed gas may contain 1% or more of oxygen.

According to the present invention, in the semiconductor laser device described above, the sealed gas may contain oxygen and an inert gas.

According to the present invention, in the semiconductor laser device described above, the inert gas may be at least one type of inert gas selected from the group of nitrogen, helium, neon, argon, xenon, and krypton.

According to the present invention, in the semiconductor laser device described above, the sealed gas may be dry air.

According to the present invention, in the semiconductor laser device described above, the dew point of the sealed gas may be −10° C. or less.

### BRIEF DESCRIPTION OF THE DRAWINGS

FIG. 1 is a diagram schematically showing the structure of a nitride semiconductor light-emitting device according to the present invention.

### DETAILED DESCRIPTION OF PREFERRED EMBODIMENTS

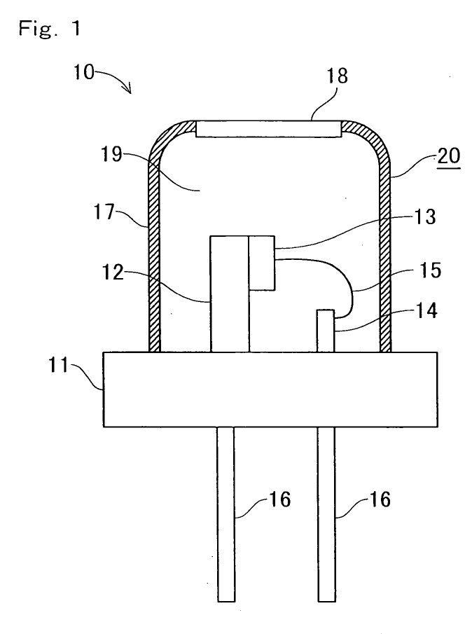

Hereinafter, an embodiment of the present invention will be described with reference to the accompanying drawing. FIG. 1 is a diagram schematically showing the structure of a nitride semiconductor light-emitting device according to the present invention.

In the nitride semiconductor light-emitting device 10, on the top surface of a stem 11, a heatsink 12 and an electrode pin 14 are provided; on the bottom surface of the stem 11, two electrode leads 16 are provided. On the heatsink 12, a nitride semiconductor laser element 13 is provided as a nitride semiconductor light-emitting element. The nitride semiconductor laser element 13 and the electrode pin 14 are electrically connected together by a wire 15.

On the top surface of the stem 11, a cap 17 is also provided. The stem 11 and the cap 17 together form a package 20. The cap 17 is fitted with a window 18 formed of glass to let out the laser light emitted from the nitride semiconductor laser element 13. The package 20 encloses the heatsink 12, the nitride semiconductor laser element 13, the electrode pin 14, and the wire 15, and has sealed therein a sealed atmosphere 19.

The nitride semiconductor laser element 13 is an element in the form of a chip that is produced by cleaving and thereby splitting a wafer having nitride semiconductor layers formed therein and then subjected to further processing such as electrode formation, wherein the nitride semiconductor layers are composed of a p-type nitride semiconductor layer doped with an acceptor impurity, an n-type nitride semiconductor layer doped with a donor impurity, and a quantum-well active layer formed of a nitride semiconductor. When a voltage is applied between the p-type and n-type semiconductors to pass a drive current therebetween, the p-n junction layer between them, at which they are jointed together, emits light. The light resonates between resonance surfaces, which are two parallel mirror surfaces formed at cleavage surfaces and having different reflectivities, and is thereby amplified until laser light is emitted through the resonance surface having the lower reflectivity. The laser light emitted from the nitride semiconductor laser element 13 passes through the window 18 to get out of the package.

In this embodiment, the stem 11 has a Fe base member coated with a Cu/Ni/Au-plated layer as a metalized layer. The heatsink 12 has a Cu base member coated with a Cu/Ni/Au-plated layer as a metalized layer, like the one provided on the current detector 11. The stem 11 and the heatsink 12 are brazed together, and the heatsink 12 and the nitride semiconductor laser element 13 are bonded together with AuSn solder. The cap 17 has, for example, a 45-alloy (Fe/45% Ni alloy) base member of which the inner and outer surfaces are plated with Ni and Pd. The cap 17 is pressure-bonded to the stem 11 under electric discharge. The window 18 is bonded to the cap 17 with low-melting glass. The Ni and Pd coating on the surface of the cap 17 may be formed by any process other than plating, for example by sputtering.

It is advisable to seal in, as the sealed atmosphere 19, dry air, or a mixed gas of oxygen and an inert gas, for example a mixed gas of 80% nitrogen and 20% oxygen. This ensures that the nitride semiconductor light-emitting device 10 operates stably for a long time with no increase in the driving voltage. The oxygen concentration in the sealed atmosphere 19 is permissibly 1 ppm or more but 100% or less, preferably 1,000 ppm or more, and more preferably 1% or more.

To prevent the nitride semiconductor laser element 13 from being contaminated with moisture, the dew point of the gas used as the sealed atmosphere 19 here is preferably −10° C. or less, and more preferably −30° C. or less. Such contamination with moisture is particularly notable when, as the light-emitting element, one whose light output is locally strong, for example a semiconductor laser element, is used, and when the light-emitting element emits light in a short wavelength region from blue to ultraviolet, that is, when it is a nitride semiconductor light-emitting element.

Now, the results of reliability tests conducted with the nitride semiconductor light-emitting device 10 of the embodiment will be presented.

The nitride semiconductor light-emitting device 10 structured as described above was combined with 12 different gases listed in Table 1 as the sealed atmosphere 19 sealed therein to prepare different samples, which were then subjected to aging tests in which they where driven at a constant current of 150 mA in a 60° C. atmosphere. Here, all the gasses had a dew point of −40° C. and, of the 12 gasses, four did not fulfill the oxygen concentration condition noted above, so as to serve as control examples. When a nitride semiconductor laser device exhibited an increase of 1 V or more in its driving voltage relative to the initial value (about 5 V) within 50 hour after it had started to be driven, it was evaluated as defective. The results of this evaluation are shown together in Table 1.

TABLE 1

| | | Defect |
|---|---|---|
| | Sealed Atmosphere Composition | Rate |
| Embodying Example 1 | Dry Air (about 78% N₂, about 21% O₂) | 0% |
| Embodying Example 2 | N₂ + O₂ Mixed Gas, with 80% O₂ | 0% |
| Embodying Example 3 | N₂ + O₂ Mixed Gas, with 60% O₂ | 0% |
| Embodying Example 4 | N₂ + O₂ Mixed Gas, with 40% O₂ | 0% |
| Embodying Example 5 | N₂ + O₂ Mixed Gas, with 20% O₂ | 0% |
| Embodying Example 6 | N₂ + O₂ Mixed Gas, with 10% O₂ | 0% |
| Embodying Example 7 | N₂ + O₂ Mixed Gas, with 1% O₂ | 0% |
| Embodying Example 8 | N₂ + O₂ Mixed Gas, with 1000 ppm O₂ | 70% |
| Control Example 1 | N₂ + O₂ Mixed Gas, with 100 ppm O₂ | 100% |
| Control Example 2 | N₂ + O₂ Mixed Gas, with 10 ppm O₂ | 100% |
| Control Example 3 | N₂ + O₂ Mixed Gas, with 1 ppm O₂ | 100% |
| Control Example 4 | Pure N₂ gas | 100% |

These results show the following. As the nitride semiconductor light-emitting device 10 is driven, its temperature rises, and the hydrogen occluded in the Ni and Pd with which the cap 17 is plated is released into the sealed atmosphere 19. In Control Examples 1 to 4, supposedly, the released hydrogen caused an increase in the resistivity of the nitride semiconductor laser element 13, and hence an increase in its driving voltage, making all samples defective. On the other hand, in Embodying Examples 1 to 8, many samples stayed non-defective; in particular, in Embodying Examples 1 to 7, almost all samples stayed non-defective. In these, supposedly, the oxygen contained at a given or higher concentration in the sealed atmosphere 19 reduced the increase in the resistivity of the nitride semiconductor laser element 13 caused by the released hydrogen.

The above observation makes it clear that the concentration of oxygen is an important factor in the prevention of defects in the nitride semiconductor light-emitting device of the invention. At oxygen concentrations of 1,000 ppm or less, the defect rate is high; at oxygen concentrations of 100 ppm or less, the defect rate is 100%. Hence, the oxygen concentration in the sealed atmosphere 19 is preferably 1,000 ppm or higher, and more preferably 1% or more. In this embodiment, defect evaluation is done for 50 hours of driving; in cases where operation reliability needs to be ensured for longer spans of time, presumably, higher oxygen concentrations of about 40% or more are preferred.

For samples of the nitride semiconductor light-emitting device 10 having dry air sealed therein as the sealed atmosphere 19 and those having pure N₂ gas sealed therein, the hydrogen concentration in the nitride semiconductor layers of the nitride semiconductor laser element 13 was measured before and after the aging tests. Before the aging tests, the hydrogen concentration was equal in samples in which the sealed atmosphere 19 was dry air and those in which it was pure N₂ gas. On the other hand, after the aging tests, in samples in which the sealed atmosphere 19 was dry air, the hydrogen concentration remained unchanged from before and, in contrast, in samples in which the sealed atmosphere 19 was pure N₂ gas, the hydrogen concentration raised by 30 to 40% from before. This, supposedly, caused the increase in the driving voltage in the aging tests. Thus, presumably, adding oxygen to the sealed atmosphere 19 helps reduce the absorption, by the nitride semiconductor layers, of the hydrogen released into the nitride semiconductor light-emitting device 10 from the Ni and Pd on the inner surface of the cap.

In the embodiment, in the cap 17, Ni and Pd are used as metals that can occlude hydrogen; instead, any other material that contains at least one type of metal selected from the group of Ti, Zr, Hf, V, Nb, Ta, Ni, and Pd may be used to obtain similar effects. The use of such a material is not limited to the plating on the cap 17; it may be used in any member, including the cap 17, that is kept in contact with the sealed atmosphere 19, for example in the stem 11 and the heatsink 12, to obtain similar effects. In the embodiment, the nitride semiconductor laser element 13 is mounted directly on the heatsink 12; however, a submount may be interposed between them, in which case the just-mentioned material may be used in the submount to obtain similar effects.

In the reliability tests described above, as the sealed atmosphere 19, nitrogen gas, which is an inert gas, having oxygen added thereto has been proved to offer the desired effects; instead, as the inert gas, at least one type of inert gas selected from the group of nitrogen, helium, neon, argon, xenon, and krypton may be used to obtain similar effects.

The present invention is effective in semiconductor elements that contain a material whose electrical characteristics may vary in the presence of hydrogen. Such semiconductor elements include AlGaAs-based semiconductor elements, AlGaInP-based semiconductor elements, and AlGaInN-based semiconductor elements, of which the last mentioned are so-called nitride semiconductor elements. Since the characteristics of nitride semiconductor elements are particularly liable to vary in the presence of hydrogen, the effects of the present invention are more notable with them.

Moreover, in nitride semiconductor light-emitting elements, the present invention offers its effects when they contain a p-type nitride semiconductor doped with an acceptor impurity. If this p-type nitride semiconductor is AlGaN, as compared with when it is GaN or like, it is more difficult to increase the hole concentration, and an increase in resistivity attributable to hydrogen is more likely. This makes the effects of the present invention more notable.

In the embodiment, used as a nitride semiconductor light-emitting element is a nitride semiconductor laser element 13, which is a light-emitting diode exploiting laser oscillation, that is, a laser diode. Instead, any other type of light-emitting element may be used, for example a light-emitting diode that relies mainly on spontaneous light emission, or a super-luminescent diode that exploits both spontaneous light emission and laser oscillation.

What is claimed is:

1. A nitride semiconductor light-emitting device comprising:
a package composed of a stem and a cap fitted on the stem;
a nitride semiconductor light-emitting element provided inside the package; and
a sealed gas sealed inside the package,
wherein
a material that can occlude hydrogen is provided inside the package, and
the sealed gas contains oxygen.

2. The nitride semiconductor light-emitting of claim 1,
wherein the material that can occlude hydrogen is formed in an inner surface of the cap.

3. The nitride semiconductor light-emitting of claim 2,
wherein the material that can occlude hydrogen contains at least one type of metal selected from the group of Ti, Zr, Hf, V, Nb, Ta, Ni, and Pd.

4. The nitride semiconductor light-emitting of claim 1,
wherein the sealed gas contains 1% or more of oxygen.

5. The nitride semiconductor light-emitting of claim 1,
wherein the sealed gas contains oxygen and an inert gas.

6. The nitride semiconductor light-emitting of claim 5,
wherein the inert gas is at least one type of inert gas selected from the group of nitrogen, helium, neon, argon, xenon, and krypton.

7. The nitride semiconductor light-emitting of claim 1,
wherein the sealed gas is dry air.

8. The nitride semiconductor light-emitting of claim 1,
wherein a dew point of the sealed gas is −10° C. or less.
